(19) United States
(12) Patent Application Publication
(10) Pub. No.: US 2026/0142440 A1
(43) Pub. Date: May 21, 2026

(54) Method for the Flexible Design of the Index Confinement in Overgrowth-Based Vertical Cavity Surface Emitting Lasers

(71) Applicant: II-VI Delaware, Inc., Wilmington, DE (US)

(72) Inventors: Wilfried Maineult, Zurich (CH); Stefano Tirelli, Zurich (CH); Antoine Philippe Pissis, Meilen (CH); Evgeny Zibik, Zurich (CH)

(21) Appl. No.: 18/953,619

(22) Filed: Nov. 20, 2024

(51) Int. Cl. H01S 5/183

(52) U.S. Cl. CPC H01S 5/18311

(57) ABSTRACT

A Vertical Cavity Surface-Emitting Laser (VCSEL) has a body comprising a vertical stack of semiconductor layers one on top of the other, including: a current confinement region including an area of low resistance to current flow defined by an area of high resistance to current flow, and a first epitaxial sublayer disposed proximate to the current confinement region, the first epitaxial sublayer including a protrusion or a recess defines a main cavity, and the balance of the first epitaxial sublayer defines an outer cavity; wherein the protrusion or recess is defined by a physical step h that is predetermined according to the equation: qλ₀−mλ₁=n₀h where λ₀ is resonant wavelength of light in the main cavity, λ₁ is resonant wavelength of light in the outer cavity, q is a half-integer positive number, n₀ is effective refractive index in the main cavity, and m is a constant.

### BACKGROUND OF THE INVENTION

### Field of the Invention

The present disclosure describes Vertical Cavity Surface-Emitting Lasers (VCSELs) that have customizable index confinement constraints.

### Description of Related Art

Heretofore, VCSELs with oxide apertures provide guided waveguides with effective refractive index contrast of about 1-2%, thus efficiently confining the optical modes. In the prior art VCSELs, oxide apertures are used to define both the current confinement as well as the index or light confinement. When single mode behavior is required, the oxide aperture needs to be reduced to 4 μm or below, which proves challenging to be done reproducibly.

Additional mode selection elements on the top of the VCSEL device may be used to provide mode selectivity. In one example, a small metal aperture may be introduced on top of the VCSEL device to filter the unwanted higher order modes. (See Ueki et al., “Single-Transverse-Mode 3.4-mW Emission of Oxide-Confined 780-nm VCSELs,” IEEE Photonics Technology. Letters, vol. 11, no. 12, pp. 1539-1541, 1999). In another example, a “mode-filtering” approach may implement a surface relief on the top surface of the VCSEL device within the emission area. With this technique, a VCSEL with up to 6.5 mW of single mode power was reported. (See Haglund et al. “High-Power Single Transverse and Polarization Mode VCSEL for Silicon Photonics Integration.” Vol. 27, No. 13, Optics Express 18892, 2019). Yet another example utilized an impurity-induced disorder of the top Distributed Bragg Reflector (DBR) mirror to reduce reflectivity and, hence, suppress higher order modes. This resulted in a VCSEL emitting ˜10 mW of single mode power (See Su et al., “High-power single-mode vertical-cavity surface-emitting lasers using strain controlled disorder-defined apertures”, Appl. Phys. Lett. 119, 241101, 2021). These methods all rely on introducing optical losses for high order modes.

Yet another example customized the mode shape by engineering the index confinement, e.g., by etching a photonic-crystal-like structure in the epilayer. (See Siriani et al., “Mode Control in Photonic Crystal Vertical-Cavity Surface-Emitting Lasers and Coherent Arrays”, IEEE Journal of Selected Topics in Quantum Electronics, Vol. 15, No. 3, pp. 909-917, 2009). The methods discussed thus far use one or more current-confining layers, which usually also lead to light confinement by introducing an increase of the refractive index in the VCSEL aperture. The magnitude of the refractive index step introduced in such methods often has some intrinsic technological limitations.

Mode control in VCSELs is crucial for many applications. In some cases, single or few-modes operation is beneficial and sometimes even necessary. This is the case of, e.g., optical communication, where the presence of many optical modes impairs the relative noise or increases optical dispersion because of the linewidth broadening. In other cases, such as when a VCSEL is used as a projecting light source, for example for sensing application, a higher-mode order operation is beneficial to have a uniform energy distribution across the emission angle. In both cases, the freedom of defining the optical mode may be an asset in attaining the required performance.

In conventional oxide-aperture VCSELs, the oxide aperture defines the current-confinement as well as the index-confinement region. While the process is straightforward, there are limitations to this approach: as not being able to define very small mode volumes, for example to promote single-mode operation, or having variations on the oxidation depth, which also impacts the mode shape and the yield across the wafer. In addition, the magnitude of the refractive index contrast between the light-emitting region and the surroundings is essentially fixed by the difference between the refractive indexes of the oxidized and the unoxidized oxide aperture formed in a layer of AlGaAs, which is a commonly used material to fabricate oxide aperture VCSELs.

Some methods rely on the definition of index confinement through a modification of the structure within the resonant cavity of the VCSEL. In some cases, the structuring can define both the index and current confinement, e.g., by implementing different thicknesses and/or etching a tunnel junction or blocking layer. Index confinement may be used interchangeably with mode or optical or light confinement as is understood to be the guided propagation of an electromagnetic wave through a restricted area. Index confinements often faces limitations due to dependence on multiple factors (material, temperature, carrier) making it difficult to maintain fine variations in a controlled manner.

It would therefore be desirable to provide VCSELs having an index confinement that is not so limited and related to a modifiable physical structure.

### SUMMARY

Disclosed herein are VCSELs fabricated by epitaxial growth techniques like Metal Organic Chemical Vapor Deposition (MOCVD). An implementation of overgrowth means that the full epitaxial structure of the VCSEL is fabricated in two steps. In the first step of the growth, the last epitaxial layer is patterned and partially etched away to define the current-confining region that defines the VCSEL aperture. The VCSEL structure is then completed with a second epitaxial growth (overgrowth) that may add a second epitaxial layer and upper DBR mirror layer on top of the patterned structure.

Between the two epitaxial growth processes, a first epitaxial layer is patterned to create a protuberance or a recess that will define the index confinement. The patterning of this layer defines the characteristics of the emission area of the VCSEL. This feature, identified by height h may be obtained by a lithographic process that involves masking the epitaxial layer with a suitable mask (e.g., resist), exposing it and developing part of it. The exposed areas are then etched for a total depth h by a standard wet or dry etching technique. The remaining mask is then removed, and the surface is cleaned and prepared for the subsequent epitaxial growth process (overgrowth).

According to non-limiting embodiments or aspects, provided is a vertical cavity surface-emitting laser (VCSEL) comprising: a body comprising a vertical stack of semiconductor layers one on top of the other, the stack of semiconductor layers comprises: a current confinement region including an area of low resistance to current flow defined by an area of high resistance to current flow, whereupon vertical current flow in the stack of semiconductor layers is directed by the area of high resistance to current flow of the current confinement region through the area of low resistance to current flow of the current confinement region; and a first epitaxial sublayer disposed proximate to the current confinement region, the first epitaxial sublayer including a protrusion or a recess disposed proximate to the area of low resistance to current flow of the current confinement region, the protrusion or recess defines a main cavity, and the balance of the first epitaxial sublayer defines an outer cavity; the protrusion or recess is defined by a physical step h that is predetermined according to the equation: qλ₀−mλ₁=n₀h where λ₀ is resonant wavelength of light in the main cavity, λ₁ is resonant wavelength of light in the outer cavity, q is a half-integer positive number, n₀ is effective refractive index in the main cavity, and m is a constant.

In non-limiting embodiments or aspects, the stack of semiconductor layers include in order: a first Distributed Bragg Reflection (DBR) mirror layer; a cavity layer including an active region; the first epitaxial sublayer and the current confinement region and a second DBR mirror layer. In non-limiting embodiments or aspects, the stack of semiconductor layers further includes: a substrate layer below the stack of semiconductor layers; a first contact on a side of the stack of semiconductor layers opposite the substrate layer; and a second contact on a side of the substrate layer opposite the stack of semiconductor layers, or on a side of the body, or on the side of the stack of semiconductor layers opposite the substrate layer, the first contact is in electrical contact only with the side of the stack of semiconductor layers opposite the substrate layer and the second contact is in electrical contact only with the side of the substrate layer opposite the stack of semiconductor layers.

In non-limiting embodiments or aspects, the area of high resistance to current flow of the current confinement region surrounds the area of low resistance to current flow of the current confinement region. In non-limiting embodiments or aspects, the protrusion or the recess of the first epitaxial sublayer is positioned in alignment with the area of low resistance to current flow of the current confinement region. In non-limiting embodiments or aspects, the area of low resistance to current flow of the current confinement region is circular shaped. In non-limiting embodiments or aspects, the protrusion or the recess of the first epitaxial sublayer is coaxial with the circular shaped current confinement region.

In non-limiting embodiments or aspects, the protrusion comprises one or more tunnel junctions.

In non-limiting embodiments or aspects, the recess comprises one or more etched regions.

In non-limiting embodiments or aspects, the current confinement region comprises one or more oxidized or implanted semiconductor layers.

In non-limiting embodiments or aspects, m is selected from a set of positive, half-integer values.

In non-limiting embodiments or aspects, λ₀ is in the range of about 680 to 2600 nm.

In non-limiting embodiments or aspects, h is selected in the range of −500 to 500 nm.

In non-limiting embodiments or aspects, the first epitaxial sublayer includes a recess and h is a negative value.

In non-limiting embodiments or aspects, the VCSEL operates with a first guided mode defined by an index contrast Δn<0, wherein Δn is effective index confinement is given by: Δn/n₀=(λ₁−λ₀)/λ₀. In non-limiting embodiments or aspects, h is a negative value and λ₁<λ₀. In non-limiting embodiments or aspects, the VCSEL also comprises sections that support anti-guided modes with an index contrast Δn>0.

In non-limiting embodiments or aspects, the VCSEL further comprises a second epitaxial sublayer proximate to the first epitaxial sublayer. In non-limiting embodiments or aspects, the stack of semiconductor layers further includes: a substrate layer below the stack of semiconductor layers; a first contact on a side of the stack of semiconductor layers opposite the substrate layer; and a second contact on a side of the substrate layer opposite the stack of semiconductor layers, or on a side of the body, or on the side of the stack of semiconductor layers opposite the substrate layer, the first contact is in electrical contact only with the side of the stack of semiconductor layers opposite the substrate layer and the second contact is in electrical contact only with the side of the substrate layer opposite the stack of semiconductor layers.

In non-limiting embodiments or aspects, for the VCSEL: when the first epitaxial sublayer includes the protrusion, the second epitaxial sublayer also includes a protrusion aligned with the protrusion of the first epitaxial sublayer; and the protrusion of the second epitaxial sublayer projects into a space surrounded by the area of high resistance to current flow of the current confinement region.

Further embodiments or aspects are set forth in the following numbered clauses:

Clause 1: A vertical cavity surface-emitting laser (VCSEL) comprising: a body comprising a vertical stack of semiconductor layers one on top of the other, wherein the stack of semiconductor layers comprises: a current confinement region including an area of low resistance to current flow defined by an area of high resistance to current flow, whereupon vertical current flow in the stack of semiconductor layers is directed by the area of high resistance to current flow of the current confinement region through the area of low resistance to current flow of the current confinement region; and a first epitaxial sublayer disposed proximate to the current confinement region, the first epitaxial sublayer including a protrusion or a recess disposed proximate to the area of low resistance to current flow of the current confinement region, wherein the protrusion or recess defines a main cavity, and the balance of the first epitaxial sublayer defines an outer cavity; wherein the protrusion or recess is defined by a physical step h that is predetermined according to the equation: qλ₀−mλ₁=n₀h where λ₀ is resonant wavelength of light in the main cavity, λ₁ is resonant wavelength of light in the outer cavity, q is a half-integer positive number, n₀ is effective refractive index in the main cavity, and m is a constant.

Clause 2: The VCSEL of clause 1, wherein the stack of semiconductor layers include in order: a first Distributed Bragg Reflection (DBR) mirror layer; a cavity layer including an active region; the first epitaxial sublayer and the current confinement region and a second DBR mirror layer.

Clause 3: The VCSEL of any of clauses 1 or 2, wherein the stack of semiconductor layers further includes: a substrate layer below the stack of semiconductor layers; a first contact on a side of the stack of semiconductor layers opposite the substrate layer; and a second contact on a side of the substrate layer opposite the stack of semiconductor layers, or on a side of the body, or on the side of the stack of semiconductor layers opposite the substrate layer, wherein the first contact is in electrical contact only with the side of the stack of semiconductor layers opposite the substrate layer and the second contact is in electrical contact only with the side of the substrate layer opposite the stack of semiconductor layers.

Clause 4: The VCSEL of any of clauses 1-3, wherein the area of high resistance to current flow of the current confinement region surrounds the area of low resistance to current flow of the current confinement region.

Clause 5: The VCSEL of any of clauses 1-4, wherein the protrusion or the recess of the first epitaxial sublayer is positioned in alignment with the area of low resistance to current flow of the current confinement region.

Clause 6: The VCSEL of any of clauses 1-5, wherein the area of low resistance to current flow of the current confinement region is circular shaped.

Clause 7: The VCSEL of any of clauses 1-6, wherein the protrusion or the recess of the first epitaxial sublayer is coaxial with the circular shaped current confinement region.

Clause 8: The VCSEL of any of clauses 1-7, wherein the protrusion comprises one or more tunnel junctions.

Clause 9: The VCSEL of any of clauses 1-8, wherein the recess comprises one or more etched regions.

Clause 10: The VCSEL of any of clauses 1-9, wherein the current confinement region comprises one or more oxidized or implanted semiconductor layers.

Clause 11: The VCSEL of any of clauses 1-10, wherein m is selected from a set of positive, half-integer values.

Clause 12: The VCSEL of any of clauses 1-11, wherein λ₀ is in the range of about 680 to 2600 nm.

Clause 13: The VCSEL of any of clauses 1-12, wherein h is selected in the range of −500 to 500 nm.

Clause 14: The VCSEL of any of clauses 1-13, wherein the first epitaxial sublayer includes a recess and h is a negative value.

Clause 15: The VCSEL of any of clauses 1-14, wherein the VCSEL operates with a first guided mode defined by an index contrast Δn<0, wherein Δn is effective index confinement is given by: Δn/n₀=(λ₁−λ₀)/λ₀.

Clause 16: The VCSEL of any of clauses 1-15, wherein h is a negative value and λ₁<λ₀.

Clause 17: The VCSEL of any of clauses 1-16, wherein the VCSEL also comprises sections that support anti-guided modes with an index contrast Δn>0.

Clause 18: The VCSEL of any of clauses 1-17, further comprising a second epitaxial sublayer proximate to the first epitaxial sublayer.

Clause 19: The VCSEL of any of clauses 1-18, wherein the stack of semiconductor layers further includes: a substrate layer below the stack of semiconductor layers; a first contact on a side of the stack of semiconductor layers opposite the substrate layer; and a second contact on a side of the substrate layer opposite the stack of semiconductor layers, or on a side of the body, or on the side of the stack of semiconductor layers opposite the substrate layer, wherein the first contact is in electrical contact only with the side of the stack of semiconductor layers opposite the substrate layer and the second contact is in electrical contact only with the side of the substrate layer opposite the stack of semiconductor layers.

Clause 20: The VCSEL of any of clauses 1-19, wherein: when the first epitaxial sublayer includes the protrusion, the second epitaxial sublayer also includes a protrusion aligned with the protrusion of the first epitaxial sublayer; and the protrusion of the second epitaxial sublayer projects into a space surrounded by the area of high resistance to current flow of the current confinement region.

### BRIEF DESCRIPTION OF THE DRAWING(S)

FIG. 1 is an enlarged schematic side view of an example VCSEL in accordance with the principles of the present disclosure comprising a first epitaxial sublayer including a tunnel junction and/or a current confinement region, and a second epitaxial sublayer above the current confinement region.

FIG. 2 is an isolated schematic side view of the example first epitaxial sublayer, current confinement region, and second epitaxial sublayer, of the VCSEL shown in FIG. 1.

FIG. 3 is an enlarged schematic side view of another example VCSEL in accordance with the principles of the present disclosure comprising a first epitaxial sublayer including a recess, a current confinement region proximate to the first epitaxial sublayer, and a second epitaxial sublayer above the current confinement region.

FIG. 4 is an isolated schematic side of the example first epitaxial sublayer, current confinement region, and second epitaxial sublayer of the VCSEL shown in FIG. 3.

FIG. 5 is an enlarged schematic side view of an example VCSEL in accordance with the principles of the present disclosure comprising a first epitaxial sublayer including a tunnel junction having a height h, a current confinement region proximate to the first epitaxial sublayer, and a second epitaxial sublayer above the current confinement region.

FIG. 6 is an enlarged schematic side view of an example VCSEL in accordance with the principles of the present disclosure comprising a first epitaxial sublayer including a tunnel junction having a height h, a current confinement region proximate to the first epitaxial sublayer, and a second epitaxial sublayer above the current confinement region.

FIG. 7 is an enlarged schematic side view of another example VCSEL in accordance with the principles of the present disclosure comprising a first epitaxial sublayer including a tunnel junction and a current confinement region proximate to the first epitaxial sublayer but excluding the second epitaxial sublayer shown in FIG. 1.

FIG. 8 is an enlarged schematic side view of another example VCSEL in accordance with the principles of the present disclosure comprising a first epitaxial sublayer including a recess and a current confinement region proximate to the first epitaxial sublayer but excluding the second epitaxial sublayer shown in FIG. 3.

FIG. 9 is an enlarged schematic side view of another example VCSEL in accordance with the principles of the present disclosure comprising a first epitaxial sublayer including a tunnel junction, a current confinement region proximate to the first epitaxial sublayer, and a second epitaxial sublayer including an optional protrusion or bump above the protrusion or bump of the current confinement region.

FIG. 10 is an enlarged schematic side view of another example VCSEL in accordance with the principles of the present disclosure comprising a first epitaxial sublayer including a recess, a current confinement region proximate to the first epitaxial sublayer, and a second epitaxial sublayer including an optional recess above the recess the current confinement region.

FIG. 11A is an enlarged schematic side view of an example VCSEL in accordance with the principles of the present disclosure including a first epitaxial sublayer with a tunnel junction where etching of the first sublayer implements optical guiding and anti-guiding sections combined with current confinement regions.

FIG. 11B is an isolated top view of the example VCSEL shown in FIG. 11A.

FIG. 11C is an effective index profile of the example VCSEL shown in FIG. 11A.

FIG. 12A is an enlarged schematic side view of an example VCSEL in accordance with the principles of the present disclosure including a first epitaxial sublayer with a current blocking layer and illustrating confinement regions, where etching of the first sublayer implements optical guiding sections and anti-guiding sections combined with current confinement sections.

FIG. 12B is an isolated top view of the example VCSEL shown in FIG. 12A.

FIG. 12C is an effective index profile of the example VCSEL shown in FIG. 12A.

### DESCRIPTION OF THE INVENTION

Various non-limiting examples will now be described with reference to the accompanying figures where like reference numbers correspond to like or functionally equivalent elements.

For purposes of the description hereinafter, terms like “end,” “upper,” “lower,” “right,” “left,” “vertical,” “horizontal,” “top,” “bottom,” “lateral,” “longitudinal,” and derivatives thereof shall relate to the example(s) as oriented in the drawing figures. However, it is to be understood that the example(s) may assume various alternative variations and step sequences, except where expressly specified to the contrary. It is also to be understood that the specific example(s) illustrated in the attached drawings, and described in the following specification, are simply exemplary examples or aspects of the disclosure. Hence, the specific examples or aspects disclosed herein are not to be construed as limiting.

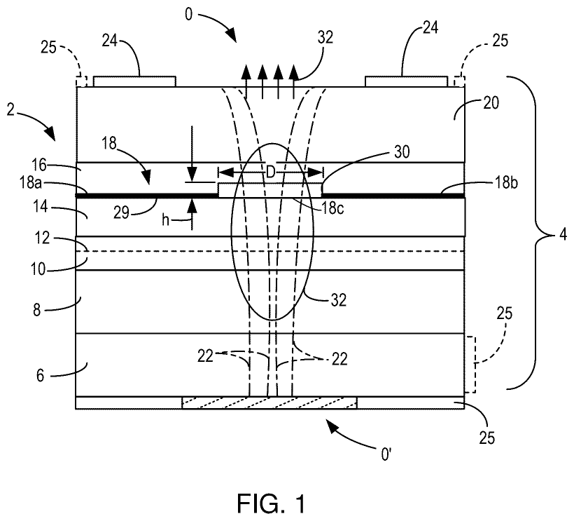

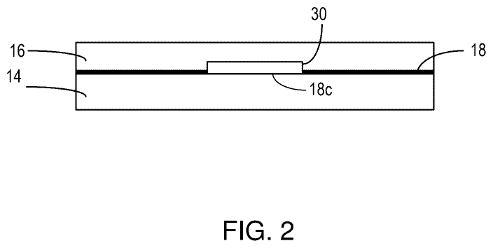

With reference to FIG. 1 and FIG. 2, one non-limiting embodiment or example VCSEL in accordance with the principles of this disclosure comprises a body 2 including a vertical stack of semiconductor layers 4, such as, for example, without limitation, layers of GaAs, AlGaAs, AlInGaAsP, InGaAs, InP, or InAlGaN, grown or deposited one atop of each other by, for example, chemical vapor deposition (CVD) or molecular beam epitaxy (MBE). The stack of semiconductor layers 4 may include, from a bottom to a top of body 2, a substrate 6, a lower Distributed Bragg Reflection (DBR) mirror layer 8, a cavity layer 10 including an active region 12, a first epitaxial sublayer 14, a current confinement region 18 which may be a part of or separate from the first epitaxial sublayer 14, a second epitaxial sublayer 16 and an upper DBR mirror layer 20. The continued growth of the upper DBR mirror layer 20 may form or define an optional cap layer as part of the upper DBR mirror layer 20.

As used herein, the first epitaxial layer is, whatever is grown in a first growth process on substrate 6. Thus, the first epitaxial layer in FIG. 1 includes sublayers 8, 10, and 14. Similarly, the second epitaxial layer is whatever is grown in a second growth process and includes sublayers 16 and 20. As shown in FIG. 1, each of the sublayers in the first epitaxial layer and second epitaxial layer are generally planar.

Herein, when used in connection with DBR mirror layers 8 and 20, the terms “first”, “lower”, “second”, and “upper” are used strictly for the purpose of description, illustration and clarity and are not to be construed in a limiting sense. Moreover, the terms “lower” and “upper,” when used in connection with DBR mirror layers 8 and 20, are used strictly in connection with the orientations shown in the figures and are not to be construed in a limiting sense. Furthermore, herein, one of the DBR mirror layers may be referred to as a first DBR mirror layer and the other DBR mirror layer may be referred to as a second DBR mirror layer strictly for the purpose of description, illustration and clarity and is not to be construed in a limiting sense.

A first electrical contact 24 may be positioned in electrical contact with a topside of the upper DBR mirror layer 20. In an example, the first electrical contact 24 may be ring shaped including an opening D for the passage of light generated by the operation of the VCSEL. However, this is not to be construed in a limiting sense since it is envisioned that the first electrical contact 24 may be any suitable and/or desirable shape or geometry that permits light generated by the operation of the VCSEL (discussed hereinafter) to exit the topside of the upper DBR mirror layer 20.

A second electrical contact 25 may, in one example, be positioned in electrical contact with a bottom side of the substrate layer 6 opposite the lower DBR mirror layer 8. In another example, the second electrical contact 25, shown in phantom in FIG. 1, may be positioned on a side of the body 2 in electrical contact with substrate 6. Herein, the terms “first” and “second,” when used in connection with contacts 24 and 25, are used strictly for the purpose of description, illustration and clarity and are not to be construed in a limiting sense.

In yet another example, also shown in phantom in FIG. 1, the second electrical contact 25 may be positioned on the topside of the upper DBR mirror layer 20, e.g., proximate, or adjacent the first electrical contact 24. In this example, the second electrical contact 25 may be electrically isolated from the topside of the upper DBR mirror layer 20 by, for example, an oxide layer, and may be electrically connected to the substrate layer 6 via an electrical conductor (not specifically shown) disposed through the body 2 or on the side of body 2.

Regardless of where the second electrical contact 25 may be disposed or positioned, the first electrical contact 24 is in electrical contact only with the topside of the cap layer 22 and the second electrical contact 25 is in electrical contact only with the substrate layer 6. An electrical bias may be applied to body 2 via the first and second electrical contacts 24 and 25. This electrical bias may cause electrical current 22 (shown by dot-dashed lines in FIG. 1) to flow in the body 2 between the substrate layer 6 and the first electrical contact 24.

Details regarding the growth or fabrication of one or more of the substrate 6, the lower DBR mirror layer 8, the cavity layer 10 including the active region 12, the upper DBR mirror layer 20, and/or the first and second electrical contacts 24 and 25 are known in the art and will not be described herein for the purpose of simplicity. Moreover, other than as may be necessary for the purpose of the present description, details regarding the growth or fabrication of one or more of the first epitaxial sublayer 14 and second epitaxial sublayer 16 are known in the art and will not be described herein for the purpose of simplicity.

For example, the VCSEL may be fabricated by an epitaxial growth technique like Metal Organic Chemical Vapor Deposition (MOCVD). An implementation of overgrowth means that the full epitaxial structure of the VCSEL is fabricated in two steps. In the first step of the growth, the first epitaxial sublayer 14 is patterned and etched away to define the current-confining region that defines the VCSEL aperture. The VCSEL structure is then completed with a second epitaxial growth (overgrowth) that adds the second epitaxial sublayer 16 and upper DBR mirror layer 20 on top of the patterned structure.

As mentioned above, between the two epitaxial growth processes, first epitaxial sublayer 14 is patterned to create a protuberance or a recess 30 that will define the index confinement. Thus, in some embodiments, the current confinement region may be the same as the optical confinement region, and in other embodiments, the current confinement region is independent from optical confinement. The patterning of this layer defines the characteristics of the emission area of the VCSEL. This feature, identified by height h may be obtained by a lithographic process that involves masking the first epitaxial sublayer 14 with a suitable mask (e.g., resist), exposing it and developing part of it. The exposed areas are then etched for a total depth h by a standard wet or dry etching technique. The remaining mask is then removed, and the surface is cleaned and prepared for the subsequent growth of the second epitaxial layer 16.

As shown, the first epitaxial sublayer 14 includes or defines on a top surface 29 thereof one or more bumps or protrusions 30, in the nature of a tunnel junction which results on the top surface 29 of the first epitaxial sublayer 14 by lithographic processes known in the art. Hereinafter, in connection with reference number 30, the terms “bump”, “protrusion” and “tunnel junction” may be used interchangeably. Tunnel junction 30 is electrically conductive and is etched away everywhere except in the center of the structure, whereupon the tunnel junction 30 has a height h. This protuberance 30 leads to current confinement, because of the formation of the tunnel junction 30 between first epitaxial sublayer 14 and second epitaxial sublayer 16 creates a current confinement region 18 that includes one or more blocking regions 18a, 18b which stop the current flow, and a region 18c having a width D where the current 22 can flow.

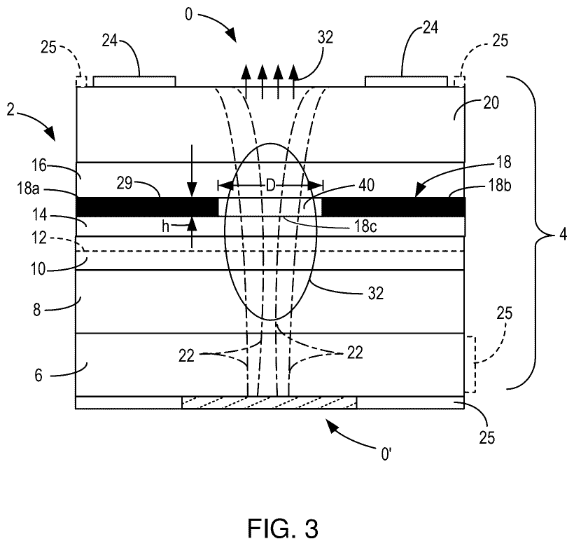

In a different embodiment of the same fabrication technique, instead of etching around the aperture, a blocking layer (not shown) already existing on first epitaxial sublayer 14 is etched away before overgrowth to create a current confinement region 18 (See FIG. 3). In both cases, the central part of the structure is where the current can flow, and stimulated emission leads to lasing. As shown, current confinement region 18 is planar, consistent with the first and second epitaxial sublayers.

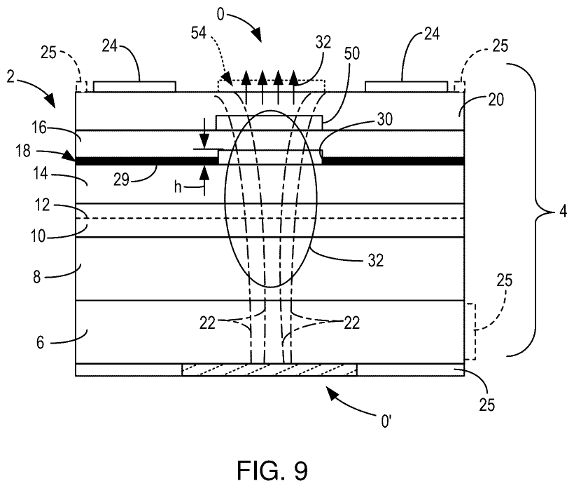

In some embodiments, the blocking layer may include an oxidized layer, a reverse biased pn junction, an implanted region, or the like. In some embodiments, such as in oxide and ion implantation, the blocking layer may be created by subsequent processes. For example, see the discussion of FIG. 9, below.

In an example, a current confinement region 18 may be present as part of first epitaxial sublayer 14 (e.g., integral to or with) or implemented above first epitaxial sublayer 14, e.g., with an oxidation step. In examples when the current confinement region 18 and first epitaxial sublayer 14 are provided by different layers, first epitaxial sublayer 14 may include a current confinement region 18 (e.g., an oxidation layer), such as shown in FIG. 3.

In some embodiments, the current confinement region 18 includes an area of low resistance 18c to current flow defined by an area of high resistance 18a and 18b to current flow, whereupon current flow in the body 2 is directed or confined through the area of low resistance 18c to current flow by the area of high resistance 18a, 18b to current flow. In one non-limiting example, the area of high resistance 18a, 18b to current flow surrounds the area of low resistance 18c to current flow, whereupon current flow in the body 2 is directed by the area of high resistance 18a, 18b to current flow through the area of low resistance 18c to current flow.

In an example, the resistance per unit area, e.g., ohms-cm², of the area of high resistance 18a, 18b to current flow is at least 10 times greater than the resistance per unit area of the area of low resistance to current flow. In an example, the area of low resistance 18c to current flow may have a resistance of 10⁻³ ohm-cm² or lower and the area of high resistance 18a, 18b to current flow may have a resistance of 0.1 ohm-cm² or higher. However, this is not to be construed in a limiting sense.

In one specific non-limiting example shown in FIGS. 1 and 2, the area of low resistance 18c to current flow may be circular shaped defined by a ring shaped inner diameter of the area of high resistance 18a, 18b to current flow. However, these shapes or geometries is/are not to be construed in a limiting sense since the use of other shapes or geometries of one or both areas of low resistance to current flow and/or the area of high resistance to current flow is/are envisioned.

In an example, the area of high resistance 18a, 18b to current flow may be formed or defined by, for example, oxidation or implantation or growth of that area of current confinement region 18 that is to define the area of high resistance to current flow. In this example, the area of low resistance 18c to current flow is an area of the current confinement region 18 that is not oxidized or implanted.

In general, the optical mode of the laser emission is set by the index confinement. The index confinement is, in turn, set by the depth h etched in layer 4, as will be explained later. In many cases the value of h has some physical or technological limits, e.g.:
The minimum thickness h that a current-conducting layer (e.g., tunnel junction) can have (see FIG. 1), therefore, the minimum etching depth necessary.
The minimum thickness that the current-blocking layer may need to have (see FIG. 3).
The minimum depth that can be reliably or reproducibly etched (e.g., technical limit).

Also, while in the case of the geometry obtained in FIG. 1, the light confinement is promoted, in the case of FIG. 3, no light confinement is introduced (e.g., anti-guiding). In all these cases, the amount of index confinement that could be introduced is limited. This disclosure provides a method to overcome this limitation, leveraging a feature of the physical mechanism that gives rise to the index confinement.

Referring back to FIG. 1, in the example VCSEL shown, the first epitaxial sublayer 14 may be positioned or disposed proximate to the current confinement region 18 which is positioned or disposed below second epitaxial sublayer 16. In an example, the first epitaxial sublayer 14 may include or define on a top surface 29 thereof one or more tunnel junctions or protrusions 30 positioned proximate to and in alignment with the area of low resistance 18c to current flow of the current confinement region 18. As shown in FIG. 1, current confinement region 18 is shown as the junction between first epitaxial sublayer 14 and second epitaxial sublayer 16.

Referring now to FIG. 2, the tunnel junction 30 of the first epitaxial sublayer 14 may be circular shaped and positioned in alignment or coaxial with the circular shaped area of low resistance 18c to current flow of the current confinement region 18. However, this is not to be construed in a limiting sense since it is envisioned that the tunnel junction 30 of the first epitaxial sublayer 14 may have any suitable and/or desirable shape or geometry (described in greater detail hereinafter) and/or the area of low resistance 18c to current flow of the current confinement region 18 may have any suitable and/or desirable shape or geometry that may the same or different than the shape or geometry of the tunnel junction 30 of the first epitaxial sublayer 14.

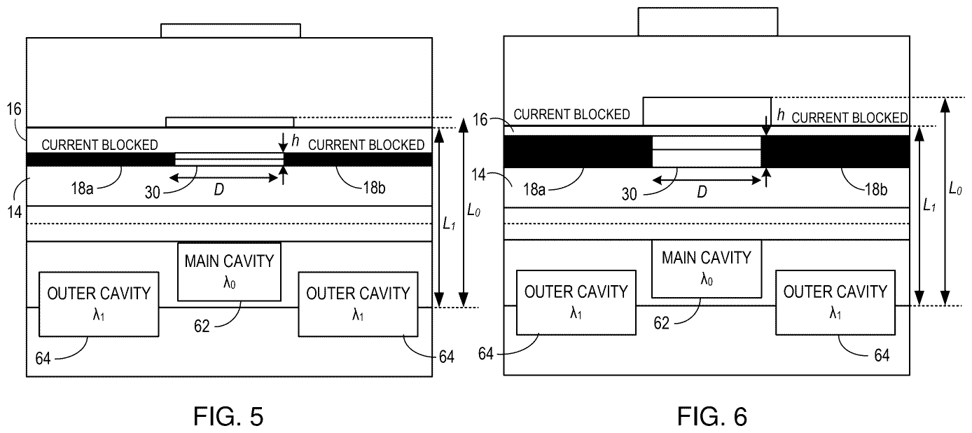

Referring to FIG. 5 and FIG. 6, in some examples, the patterning of the first epitaxial sublayer 14 may produce two regions or cavities. Namely, a main region or cavity 62 in vertical alignment with the tunnel junction 30 and where light 32 is emitted (e.g., through width D) and a secondary region or cavity 64 in vertical alignment with the/those area(s) of the first epitaxial sublayer 14 that is/are not in vertical alignment the tunnel junction 30, i.e., the area(s) surrounding the tunnel junction or protrusion 30. It should be appreciated that FIG. 5 and FIG. 6 show VCSELs similar to that of FIG. 1, but with additional details and differing heights of protrusion 30. For example, both FIG. 5 and FIG. 6 show a VCSEL with a physical step h, but the h in FIG. 6 is much larger than the h in FIG. 5.

In some embodiments, the current confinement region is proximate to the first epitaxial sublayer and the second epitaxial sublayer above the current confinement region. It should be appreciated in some embodiments, the current confinement region may be included with the first and/or second epitaxial sublayers or be independent from the epitaxial sublayers.

The resonant wavelengths of light 32 in the main region 62 and the secondary region 64 will be different and may be equal to λ₀ and λ₁, respectively. The difference between these wavelengths defines the effective index confinement of the first epitaxial sublayer 14 which determines the optical mode. In particular, the effective index confinement (Δn) is given by:

$$Δ n / {n}_{0} = ( {λ}_{1} - {λ}_{0} ) / {λ}_{0} \qquad ( Eqn . 1 )$$

where n₀ is the effective refractive index in the main region 62. Δn determines the index contrast and defines the supported lateral optical modes with a given shape or geometry of the first epitaxial sublayer 14, e.g., the maximum size of the light guiding pattern D in FIG. 1, to have single optical mode operation.

In other words, the higher Δn, the smaller D must be to have single mode operation. Therefore, the magnitude of Δn determines the maximum size of D in order to have single mode operation. In some embodiments, λ₁ is selected so that the index contrast ranges from about 0 to 50%.

λ₀>λ₁ means that the cavity is index-guided, while λ₀<λ₁ means no guiding (anti-guiding). Efficient lasing usually requires guiding behavior. Setting λ₀ and λ₁ enables engineering of the index confinement.

Referring now to FIGS. 1, 5 and 6, we observe that qλ₀=n₀L₀ where q is a half-integer positive number (q=½, 1, 3/2, 2, etc.). Physical height L₀ refers to the distance that the light traverses back and forth in the main cavity. The physical height L₀=qλ₀/n₀, is thus chosen so that the VCSEL emits in the proper wavelength λ₀. The outer cavity resonance wavelength λ₁ is otherwise determined by its physical height L₁. We observe that mλ₁=n₀L₁ for any positive value of another half-integer number m.

Controlling the index contrast is critical for some applications. For example, a small index contrast can promote single mode operation in VCSELs. Index contrast is proportional to the difference between two cavity lengths. Because there is often a technical limitation on how small one can realistically fabricate the physical step h=L₁−L₀, an alternative method to determine λ₁ and therefore the index contrast, based on the freedom of defining m is desirable. In fact, the step h could be changed within a wide range of values and still obtain the required values for λ₀ and λ₁. A general formulation of this principle is given by:

$${q λ}_{0} - {m λ}_{1} = {n}_{0} h \qquad ( Eqn . 2 )$$

where λ₀ is set based on the emission wavelength required, q determines the cavity height in λ₀ and is often subjected to constraints based on the application, and λ₁ is set to achieve the desired index contrast (according to Eqn. 1).

Based on Eqn. 1 and/or Eqn. 2, it should be appreciated that q may be chosen to determine λ₀. Similarly, m may be chosen to determine a practical and manufacturable value for h. For example, in some embodiments, λ₀ is in the range of about 680 to 2600 nm.

Still referring to FIGS. 5 and 6, each show a different way to achieve the same result. If h from FIG. 5 and h from FIG. 6 both satisfy Eqn. 2 for different values of m, then the two devices have similar index confinement properties. This provides a solution to implement single-mode emission in VCSELs in additional cases where it would otherwise be not practical. For example, in the case of index guiding, (i.e., Δn<0), the magnitude of Δn also sets the maximum size/diameter of the aperture (D) to have single-mode behavior.

In some embodiments, a very negative value for Δn means that a very low value for D, e.g., a small aperture, is needed to achieve single-mode behavior. Lowering h is the most straightforward way of achieving a less negative Δn. However, because of technical or process limitations a small h is often not practically, or reliably, attainable. Leveraging the alternative shown in FIG. 6, allows to achieve the same result with a larger and manufacturable value h.

In some embodiments, having a higher value of h may be the only way to achieve the necessary refractive index contrast. For example, refer to FIG. 3, where the device is fabricated by etching a layer within the emission region to produce a recess 40, instead of a protrusion or protuberance. As described below in more detail, a current blocking region is etched away to let the current flow within the aperture. It is worth noting that in this case h<0, because it represents a recess instead of a protrusion. A small etching may lead to an anti-guiding behavior because, λ₁>λ₀ hence Δn>0, therefore impeding efficient lasing from the device. However, assuming q=½ and setting m=1, we can still create a guiding index profile (Δn<0, λ₁<λ₀) by etching to deeper depth so that Eqn. 2 still gives a negative value for h (etching).

In some embodiments, having a higher value h may be the only way to achieve the necessary refractive index contrast. For example, refer to FIG. 3, where the device is fabricated by etching first epitaxial sublayer 14 within the emission region, instead of a protrusion or protuberance. As described below in more detail, a current blocking region is etched away to let the current flow within the aperture D. It is worth noting that in this case h<0, because it represents a recess instead of a protrusion. A small etching leads to an anti-guiding behavior because, λ₁>λ₀ hence Δn>0, therefore impeding efficient lasing from the device. However, assuming q=½ and setting m=1, we can still create a guiding index profile (Δn<0, λ₁<λ₀) by etching to deeper depth so that Eqn. 2 still gives a negative value for h (etching).

In some embodiments, h is selected in the range of about −500 to 500 nm. In some embodiments, h is selected to be in the range of about −300 to 300 nm. In some embodiments, h is selected to be in the range of about 100 to 300 nm. In some embodiments, h is selected to be in the range of about 200 to 300 nm.

In FIG. 1, the index contrast increases with higher values of the height h of the protrusion or bump 30. In use, an electrical bias applied to the first and second electrical contacts 24 and 25 causes electrical current 22 to flow vertically or substantially vertically in body 2 between the substrate layer 6 and the first electrical contact 24. This flow of electrical current 22 in body 2 is directed or confined to flow through the area of low resistance 18c to current flow by the area of high resistance 18a, 18b to current flow of the current confinement region 18. This electrical current 22 also flows through the active region 12 of the cavity layer 10 which, in response, emits light 32 (shown by the ellipse in the body 2 and by the arrows exiting the topside of the upper DBR mirror layer 20). This emitted light 32 is directed or confined, by the difference in the refractive indices of the main region of the first epitaxial sublayer 14, aligned with the tunnel junction 30, and the secondary region of the first epitaxial sublayer 14, not aligned with the tunnel junction 30, to flow through the area of low resistance 18c to current flow of the current confinement region 18 and exit the top surface of the upper DBR mirror layer 20 above the protrusion or bump 30 and the area of low resistance 18c to current flow of the current confinement region 18.

The shape or geometry of the first epitaxial sublayer 14 shown in FIG. 2 is but one non-limiting example of the shape or geometry that the first epitaxial sublayer 14, including one or more projections or bumps, such as tunnel junction 30, may have. The shape or geometry the first epitaxial sublayer 14 is not to be construed in a limiting sense since it is envisioned that the first epitaxial sublayer 14 may have any suitable and/or desirable shape or geometry deemed desirable for the VCSEL to emit light 32 having a desired shape, geometry, and/or mode for a particular application.

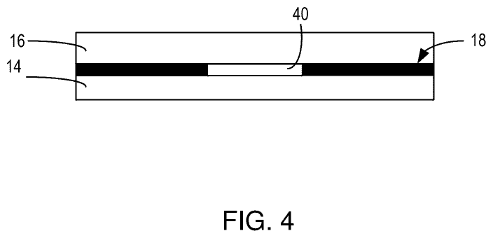

With reference to FIGS. 3 and 4 and with continuing reference to FIGS. 1 and 2, other non-limiting embodiment or example VCSELs in accordance with the principles of this disclosure may, with one exception, be similar to the example VCSELs shown in FIGS. 1 and 2 and described above. The exception is that instead of the top surface 29 of the first epitaxial sublayer 14 including one or more protrusions or bumps 30, the first epitaxial sublayer 14 of the VCSELs shown in FIGS. 3 and 4 may include one or more recesses or cavities 40 in the top surface 29 of the first epitaxial sublayer 14. The principles of operation of the VCSELs shown in FIGS. 1 and 2 and described above are applicable to the principles of operation of the VCSELs shown in FIGS. 3 and 4, respectively, and will not be further described herein to avoid unnecessary redundancy.

In general, the use of one or more recesses or cavities 40 in the top surface 29 of the first epitaxial sublayer 14 versus the use of one or more protrusions or bumps 30 may affect the shape, geometry, and/or mode of the light 32 exiting the topside of the upper DBR mirror layer 20. Stated differently, e.g., for the VCSELs shown in FIGS. 1 and 3, the light 32 exiting the topside of the upper DBR mirror layer 20 may have a different shape, geometry, and/or mode (useable for different applications) due to the presence of one or more protrusions or bumps 30 in the top surface 29 of the first epitaxial sublayer 14 of the VCSEL shown in FIG. 1 versus the presence of one or more recesses or cavities 40 in the top surface 29 of the first epitaxial sublayer 14 of the VCSEL shown in FIG. 3.

As provided above, instead of etching around the aperture, a blocking layer (not shown) already existing on first epitaxial sublayer 14 is etched away before overgrowth to create the current confinement region 18. The current confinement region may include one or more areas of blocking layers 18a and 18b that are proximate to first epitaxial sublayer 14. In some embodiments, blocking layers 18a and 18b represent a ring shaped region about a circular recess 40. The etched away portion forms recess 40, which coincides with the low resistance 18c to current flow region.

In some embodiments, the blocking layer(s) may include an oxidized layer, a reversed pn junction, an implanted region or similar.

The shape or geometry of the first epitaxial sublayer 14 shown in FIG. 4 is but one non-limiting example of the shape or geometry that the first epitaxial sublayer 14 including one or more recesses or cavities 40 may have. The shape or geometry of the first epitaxial sublayer 14 is not to be construed in a limiting sense since it is envisioned that the first epitaxial sublayer 14 may have any suitable and/or desirable shape or geometry deemed desirable for the VCSEL to emit light 32 having a desired shape, geometry, and/or mode for a particular application.

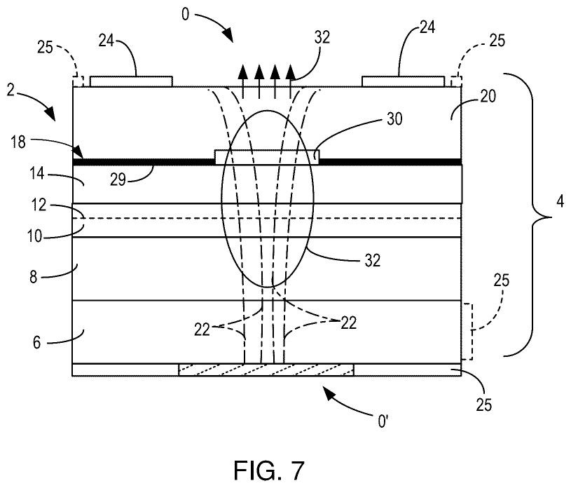

With reference to FIG. 7, another non-limiting embodiment or example VCSEL in accordance with the principles of this disclosure may, with exceptions, be similar to the example VCSEL shown in FIG. 1 and described above. One exception may include the omission or absence of second epitaxial sublayer 16 shown in FIG. 1 in the VCSEL shown in FIG. 7.

The protrusion or bump 30 of the first epitaxial sublayer 14 of FIG. 7, may have any shape or geometry deemed suitable and/or desirable for the VCSEL to emit light 32 having a desired shape, geometry, and/or mode for a particular application. Non-limiting examples of such shapes or geometries may include the first epitaxial sublayer 14 having one or more protrusions or bumps 30 as shown, for example, in FIG. 2. Accordingly, the shape of the protrusion or bump 30 shown in FIG. 7 is not to be construed in a limiting sense.

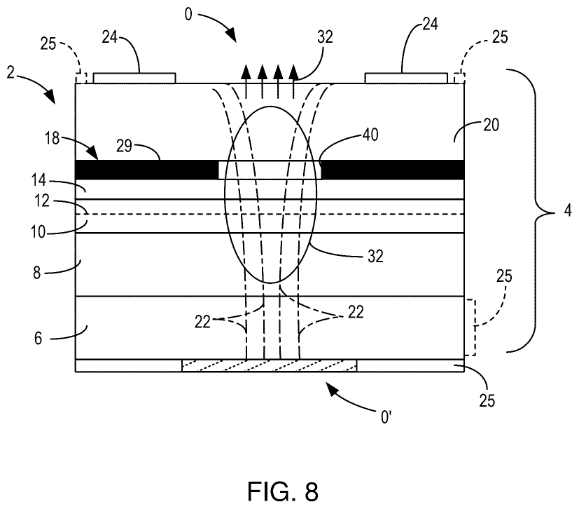

With reference to FIG. 8, another non-limiting embodiment or example VCSEL in accordance with the principles of this disclosure may, with exceptions, be similar to the example VCSEL shown in FIG. 3 and described above. One exception may include the omission or absence of the second epitaxial sublayer 16 shown in FIG. 3 in the VCSEL shown in FIG. 8.

The recess 40 of the first epitaxial sublayer 14 of FIG. 8, may have any shape or geometry deemed suitable and/or desirable for the VCSEL to emit light 32 having a desired shape, geometry, and/or mode for a particular application. Non-limiting examples of such shapes or geometries may include the first epitaxial sublayer 14 having one or more recesses or cavities 40 as shown, for example, in FIG. 4. Accordingly, the shape of the recess 40 shown in FIG. 8 is not to be construed in a limiting sense.

With reference to FIG. 9 and with continuing reference to FIG. 1 and FIG. 2, another non-limiting embodiment or example VCSEL in accordance with the principles of this disclosure may include, in an example, the one or more protrusions or bumps 30 on the top surface 29 of the first epitaxial sublayer 14 may result in one or more corresponding protrusions or bumps (not shown in FIG. 1 for the purpose of simplicity) forming on some or all of the following layers during the growth thereof over the first epitaxial sublayer 14, protrusion or bump 50 of the second epitaxial sublayer 16, and/or protrusion or bump 54 (shown in phantom) of the upper DBR mirror layer 20. In another example, the second epitaxial sublayer 16, and the upper DBR mirror layer 20 may have progressively smaller (relative to height h) protrusions or bumps above the one or more protrusions or bumps 30 on the top surface 29 of the first epitaxial sublayer 14, including, in an example, the topside of the upper DBR mirror layer 20 being planar, etc. However, these examples are not to be construed in a limiting sense since the topside surface of each layer above the protrusions or bumps 30 on the top surface 29 of the first epitaxial sublayer 14 may have a protrusion or bump or may be planar as shown in FIGS. 1 and 2.

In addition, as shown in FIG. 9, current confinement layer 18 may be a carrier depleted region due to the difference of doping type between first epitaxial sublayer 14 and second epitaxial sublayer 16 and the polarity bias applied during operation. The carrier depletion of current confinement region 18 prevents the current to drive through. Protrusion or bump 30 may include two layers doped at a higher level. The higher doping level enables conduction via Esaki band-to-band tunneling. Tunneling through the protrusion or bump 30 allows the current to drive through.

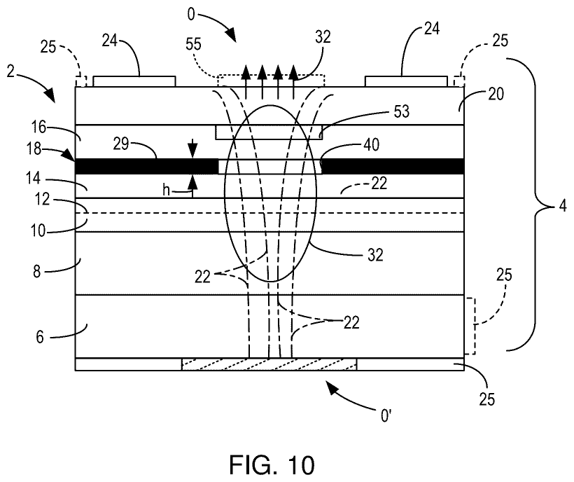

With reference to FIG. 10 and with continuing reference to FIGS. 3 and 4, another non-limiting embodiment or example VCSEL in accordance with the principles of this disclosure may include, in an example, the one or more recesses or cavities 40 on the top surface 29 of the first epitaxial sublayer 14 may result in one or more corresponding recesses or cavities 40 (not shown in FIGS. 3 and 4 for the purpose of simplicity) forming in some or all of the following layers during the growth thereof over the first epitaxial sublayer 14, recess 53 of the second epitaxial sublayer 16, and/or recess 55 (shown in phantom) of the upper DBR mirror layer 20. In another example, the second epitaxial sublayer 16, and the upper DBR mirror layer 20 may have progressively smaller (relative to height H) recesses or cavities above the one or more recesses or cavities 40 in the top surface 29 of the first epitaxial sublayer 14, including, in an example, the topside of the upper DBR mirror layer 20 being planar, etc. However, these examples are not to be construed in a limiting sense since the topside surface of each layer above the one or more recesses or cavities 40 in the top surface 29 of the first epitaxial sublayer 14 may have a recess or may be planar as shown in FIGS. 3 and 4.

Finally, herein, light 32 is described and illustrated in the figures as exiting upwardly from the topside of the upper DBR mirror layer 20. However, in an example, it is envisioned that each non-limiting embodiment or example VCSEL illustrated and described herein may be modified such that the upper DBR layer 20 has a higher reflectivity than the lower DBR layer 8 whereupon light 32 may be reflected by the upper DBR layer 20 through the stack of semiconductor layers 4 and exit downwardly through the substrate layer 6, which remains at the bottom of the stack of semiconductor layers 4.

In this example, the second electrical contact 25 may be positioned in electrical contact with the bottom side of the substrate layer 6 and may be formed with an opening O′, shown in phantom in FIGS. 1, 3, and 7-10, like the opening O shown in these figures, to allow light 32 passing downwardly through the substrate layer 6 to exit the bottom side of the substrate layer 6 through the opening O′. In an example, the first electrical contact 24 may be positioned on the topside of the stack of semiconductor layers 4, e.g., on the topside of the upper DBR mirror layer 20, and its opening O may be omitted.

In another example, a second electrical contact 25 may be positioned, as shown in phantom in FIGS. 1, 3, and 7-10, on the side of the body 2 in electrical contact with substrate 6. In yet another example, the second electrical contact 25 may be positioned, as shown in phantom in FIGS. 1, 3, and 7-10, on the topside of the stack of semiconductor layers 4, i.e., on the topside of the upper DBR mirror layer 20, proximate or adjacent the first electrical contact 24. In this latter example, the second electrical contact 25 may be electrically isolated from the topside of the stack of semiconductor layers 4 by, for example, an oxide layer, and may be electrically connected to the substrate layer 6 via an electrical conductor (not specifically shown) disposed through the body 2 or on the side of body 2.

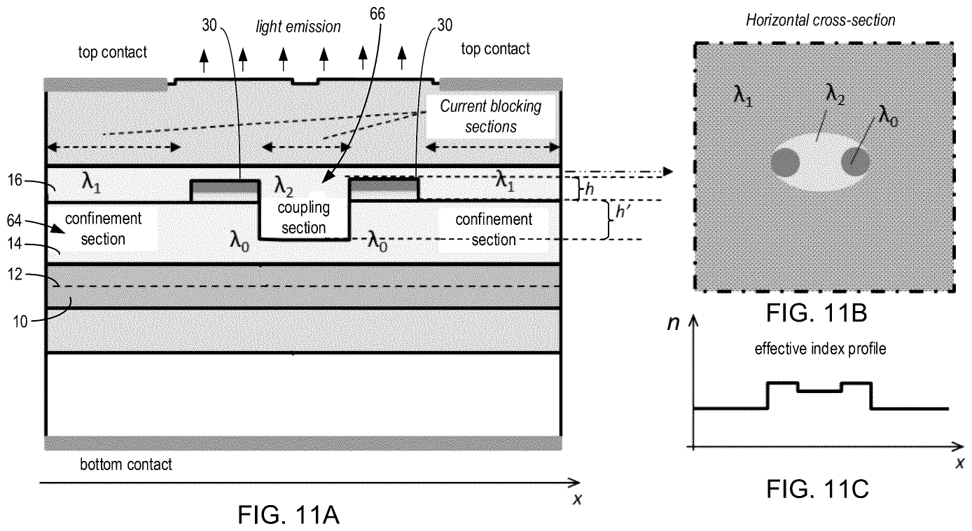

The present disclosure also allows to implement guiding and anti-guiding (coupling) sections in a single overgrowth step, using a multi-step index profile. An example of this implementation is provided in FIGS. 11A-C and 12A-C. Tuning the etch depth in accordance with Eqn. 2, and patterning the wafer appropriately, one can freely define regions with guiding and anti-guiding (coupling) properties in accordance with Eqn. 1.

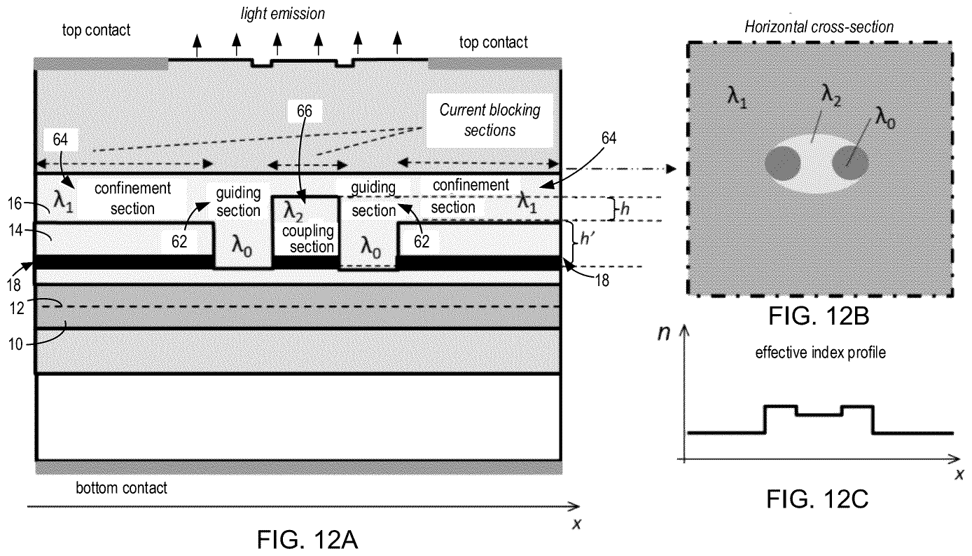

In the examples of FIGS. 11A-C and 12A-C, the etch depths of the guiding and anti-guiding sections are set to achieve a lower resonance wavelength in the middle section, with respect to the guiding sections (λ₂<λ₀), but higher than that in the outmost cavity (λ₂>λ₁). Leveraging Eqn. 2, one can implement this design with the most manufacturable etching depths. This method may enhance/control the coupling strength in multiple-cavity/emitter VCSEL arrays. A schematic implementation with two cavities is shown in FIG. 11A in combination with a tunnel junction and in FIG. 12A in combination with a blocking layer. The flexibility of the technique allows a choice of different etch depths to pattern the VCSEL cavity during the same lithographic process step when defining the index profile, shown by FIG. 11C and FIG. 12C, respectively.

With reference to FIGS. 11A-C and 12A-C, a “confinement” section is herein defined as an outer section of the VCSEL, that acts as a “cladding” section by confining the light toward the inner regions. The confinement region is also generally the region where the refractive index is the lowest.

In addition to the confinement regions, the present disclosure provides for an arbitrary number of regions with different index contrasts, i.e., different light confining and current confining properties, based on the VCSEL structure and method used for confining the current.

FIGS. 11A-C and 12A-C illustrate examples implementing coupled-cavities with current confinement based on a tunnel junction 30 (FIG. 11A) or a blocking layer 18 (FIG. 12A). In FIG. 11A, combined current and optical confinements with etching of tunnel junction 30 and profiling the cavity forming guiding 62 and coupling 66 sections are provided. In FIG. 11A, the disclosure is leveraged to define the etching depth h′ and obtain the effective index profile shown in FIG. 11C. Specifically, after the first epitaxial growth, the etching depth h is first realized by etching for a depth at least as much as the tunnel junction 30, to provide current confinement in the inner section 64. Then, the second epitaxial etch depth h′ is implemented. Because the current flow must be confined only within the guiding sections 62, the second etch depth h′ must be at least as deep as the tunnel junction 30, but implementing a lower index contrast would mean having h′ smaller than h, and not being able to confine current in the guiding sections 62, due to incomplete etching of the tunnel junction 30. Using the method described in this disclosure, a deeper etching can be implemented, while at the same time achieving a small refractive index difference with respect to the guiding sections 62 and simultaneously implementing the appropriate current confinement.

In FIG. 12A, combined current and optical confinements with etching of current blocking and profiling the cavity forming guiding 62 and coupling 66 sections are provided. In this embodiment, the current is blocked by the blocking layer 18 marked in black. Therefore, current flow is enabled by etching the blocking layer 18. Similarly to FIG. 11A, first a shallow etching depth h is implemented in order to introduce an outer index confinement 64. In order to implement current flow only in the guiding section(s) 62, we then need to etch at least as deep as the blocking layer 18, therefore removing it and enabling current flow. Leveraging the disclosure, it is then possible to design the epilayer stack in such a way that etching the deep depth h′ implements a very small effective index difference between the guiding 62 and coupling 66 sections, while simultaneously achieving current confinement by removing the blocking layer 18. The resulting optical profile is shown in FIG. 12C. The central part corresponds to the coupling sections 66, which has a slightly lower effective index than the guiding sections 62.

In these two embodiments, the current may be confined to flow in the guiding sections 62. For this to happen, only in the region where the current should flow, the tunnel junction 30 or blocking layer 18 may be preserved or etched away, respectively. This sets a minimum technical requirement for the etch depth h, equal to the thickness of the tunnel junction 30 or blocking layer 18.

In the embodiments of FIGS. 11 and 12, and shown in FIG. 11C and FIG. 12C, the same index profile may be obtained but with different etch depths h, which can be then determined using Eq. 2. The effective optical index of the coupling section 66 can be made equal, lower or higher, than that of the guiding sections 62, depending on the requirement of the application.

In some embodiments, the number of coupled emitters may be arbitrary with 2D arrangement. The same technique, with different geometries, may be used to achieve mode selection with a single or multiple cavities. In some embodiments, the number of index steps, such as shown by the index profiles of FIGS. 11C and 12C is not limited to three.

Although the disclosure has been described in detail for the purpose of illustration based on what is currently considered to be the most practical and preferred examples, it is to be understood that such detail is solely for that purpose and that the disclosure is not limited to the disclosed examples, but, on the contrary, is intended to cover modifications and equivalent arrangements that are within the spirit and scope of the appended claims. For example, it is to be understood that the present disclosure contemplates that, to the extent possible, one or more features of any example may be combined with one or more features of any other example.

For example, the disclosure provides a method for determining a manufacturable etch depth h for a wide range of index contrast Δn, for the case of lithographically defined cavity patterning. This method is also valid where cavity patterning defines only the index contrast, independently from current confinement.

Benefits associated with VCSELs made in accordance with disclosed methods include:
A VCSEL where the desired optical mode is attained by etching an arbitrarily thick section of its epitaxial structure and through overgrowth exploiting the multiple resonances within the same cavity.
A VCSEL where the index contrast has an arbitrarily low value, while the etch remains at a manufacturable depth >10 nm.
A VCSEL where mode selection is implemented by definition of coupling and guiding regions with cavity patterning and with a single overgrowth process.
A VCSEL where guiding and anti-guiding (coupling) properties are implemented with a single overgrowth step to enhance coupling between two or more cavities.
A VCSEL where multiple index steps to implement guiding and coupling sections are present in the same device, and implemented with a single overgrowth step.
A VCSEL where multiple index steps, to achieve guiding and coupling sections, are present in the same device, and implemented with a single overgrowth step, and current confinement if defined within the same processing step.

What is claimed is:

1. A vertical cavity surface-emitting laser (VCSEL) comprising:
a body comprising a vertical stack of semiconductor layers one on top of the other, wherein the stack of semiconductor layers comprises:
a current confinement region including an area of low resistance to current flow defined by an area of high resistance to current flow, whereupon vertical current flow in the stack of semiconductor layers is directed by the area of high resistance to current flow of the current confinement region through the area of low resistance to current flow of the current confinement region; and
a first epitaxial sublayer disposed proximate to the current confinement region, the first epitaxial sublayer including a protrusion or a recess disposed proximate to the area of low resistance to current flow of the current confinement region, wherein the protrusion or recess defines a main cavity, and the balance of the first epitaxial sublayer defines an outer cavity;
wherein the protrusion or recess is defined by a physical step h that is predetermined according to the equation:
$${q λ}_{0} - {m λ}_{1} = {n}_{0} h$$
where λ₀ is resonant wavelength of light in the main cavity, λ₁ is resonant wavelength of light in the outer cavity, q is a half-integer positive number, n₀ is effective refractive index in the main cavity, and m is a constant.

2. The VCSEL of claim 1, wherein the stack of semiconductor layers include in order:
a first Distributed Bragg Reflection (DBR) mirror layer;
a cavity layer including an active region;
the first epitaxial sublayer and the current confinement region
and
a second DBR mirror layer.

3. The VCSEL of claim 2, wherein the stack of semiconductor layers further includes:
a substrate layer below the stack of semiconductor layers;
a first contact on a side of the stack of semiconductor layers opposite the substrate layer; and
a second contact on a side of the substrate layer opposite the stack of semiconductor layers, or on a side of the body, or on the side of the stack of semiconductor layers opposite the substrate layer, wherein the first contact is in electrical contact only with the side of the stack of semiconductor layers opposite the substrate layer and the second contact is in electrical contact only with the side of the substrate layer opposite the stack of semiconductor layers.

4. The VCSEL of claim 1, wherein the area of high resistance to current flow of the current confinement region surrounds the area of low resistance to current flow of the current confinement region.

5. The VCSEL of claim 4, wherein the protrusion or the recess of the first epitaxial sublayer is positioned in alignment with the area of low resistance to current flow of the current confinement region.

6. The VCSEL of claim 5, wherein the area of low resistance to current flow of the current confinement region is circular shaped.

7. The VCSEL of claim 6, wherein the protrusion or the recess of the first epitaxial sublayer is coaxial with the circular shaped current confinement region.

8. The VCSEL of claim 1, wherein the protrusion comprises one or more tunnel junctions.

9. The VCSEL of claim 1, wherein the recess comprises one or more etched regions.

10. The VCSEL of claim 1, wherein the current confinement region comprises one or more oxidized or implanted semiconductor layers.

11. The VCSEL of claim 1, wherein m is selected from a set of positive, half-integer values.

12. The VCSEL of claim 1, wherein λ₀ is in the range of about 680 to 2600 nm.

13. The VCSEL of claim 1, wherein h is selected in the range of −500 to 500 nm.

14. The VCSEL of claim 1, wherein the first epitaxial sublayer includes a recess and h is a negative value.

15. The VCSEL of claim 1, wherein the VCSEL operates with a first guided mode defined by an index contrast Δn<0, wherein Δn is effective index confinement is given by:
$$Δ n / {n}_{0} = ( {λ}_{1} - {λ}_{0} ) / {λ}_{0} .$$

16. The VCSEL of claim 15, wherein h is a negative value and λ₁<λ₀.

17. The VCSEL of claim 15, wherein the VCSEL also comprises sections that support anti-guided modes with an index contrast Δn>0.

18. The VCSEL of claim 1, further comprising a second epitaxial sublayer proximate to the first epitaxial sublayer.

19. The VCSEL of claim 18, wherein the stack of semiconductor layers further includes:
a substrate layer below the stack of semiconductor layers;
a first contact on a side of the stack of semiconductor layers opposite the substrate layer; and
a second contact on a side of the substrate layer opposite the stack of semiconductor layers, or on a side of the body, or on the side of the stack of semiconductor layers opposite the substrate layer, wherein the first contact is in electrical contact only with the side of the stack of semiconductor layers opposite the substrate layer and the second contact is in electrical contact only with the side of the substrate layer opposite the stack of semiconductor layers.

20. The VCSEL of claim 19, wherein:
when the first epitaxial sublayer includes the protrusion, the second epitaxial sublayer also includes a protrusion aligned with the protrusion of the first epitaxial sublayer; and
the protrusion of the second epitaxial sublayer projects into a space surrounded by the area of high resistance to current flow of the current confinement region.
